(19) United States
(12) Patent Application Publication
(10) Pub. No.: US 2025/0120124 A1
(43) Pub. Date: Apr. 10, 2025

(54) METHOD FOR PRODUCING A MICROELECTRONIC DEVICE COMPRISING A WRAPPING GRID

(71) Applicant: COMMISSARIAT A L'ENERGIE ATOMIQUE ET AUX ENERGIES ALTERNATIVES, Paris (FR)

(72) Inventor: Sylvain BARRAUD, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/799,825

(22) Filed: Aug. 9, 2024

(30) Foreign Application Priority Data
Aug. 11, 2023 (FR) 2308689

(51) Int. Cl. H10D 30/67; H10D 30/00; H10D 30/01; H10D 62/10; H10D 62/80; H10D 62/832; H10D 64/01; H10D 84/83

(52) U.S. Cl. CPC H10D 30/6735; H10D 30/017; H10D 30/0191; H10D 30/502; H10D 30/6757; H10D 62/121; H10D 62/832; H10D 62/883; H10D 64/017; H10D 64/018; H10D 84/832

(57) ABSTRACT

A method for producing a device comprising GAA transistors. Advantageously, the channels of the transistors are produced by deposition of a semiconductor material, preferably a 2D material, after successive removal of certain layers of the initial stack. The gates-all-around are produced after selective removal of the other layers from the initial stack. The initial stack does not comprise the semiconductor material, nor the material of the gates. The subsequent deposition of the semiconductor material aims to better preserve the semiconductor material.

### TECHNICAL FIELD

The invention relates to the field of microelectronics technologies. It has a particularly advantageous application in manufacturing advanced FET (Field-Effect Transistor)-type devices with gate-all-around and with semiconductor material-based channel, in particular two-dimensional (2D) material or semiconductor oxide-based.

### PRIOR ART

The constant increase of performance of transistors has first been enabled by reducing the dimensions of transistors, for a conventional MOSFET (Metal-Oxide-Semiconductor Field-Effect Transistor) architecture based on silicon.

This conventional architecture has then given way to other types of architectures, better adapted to performances specified in technological nodes less than 12 nm. The so-called “finFET” architecture makes it possible, for example, to respond to performances fixed by 7 nm and 5 nm technological nodes.

For the next technological nodes, in particular from 3 nm and beyond, other architectures offering a better electrostatic control are necessary. An architecture considered to respond to the problems of these next technological nodes comprises gate-all-around transistors called GAA transistors stacked on one another.

In parallel to developing new architectures, materials other than silicon are considered for manufacturing channels of transistors. Recently, 2D materials, which can be constituted of one single atom layer, have appeared as promising candidates for a use in electronic and optoelectronic devices comprising one or more elements of very low thicknesses.

The document, “Challenges of Wafer-Scale Integration of 2D Semiconductors for High-Performance Transistor Circuits, Tom Schram et al., Adv. Mater., 2109796 (2022)” discloses a method for manufacturing superposed GAA transistors comprising a 2D material-based channel. In this method, the 2D materials considered are transition metal dichalcogenides in the form of monolayers. These 2D materials are easily degraded when they are subjected to an average thermal budget. Yet, the different steps of the method disclosed by this document imply a consequent thermal budget, able to thermally degrade the 2D material monolayers. It also appears that the steps of forming internal spacers and replacing the sacrificial gate imply that parts of the 2D material monolayers are freely suspended. The mechanical urges undergone by the 2D material monolayers are also able to degrade the final structure and/or the targeted performance. The thermal and/or mechanical aspects of this manufacturing method are not completely suitable for 2D material monolayers. Consequently, developing such a method requires significant modifications and adaptations of current technological methods. The modifications and adaptations proposed to date impose additional costs and/or limitations for the industrial manufacture of 2D material-based GAA transistors.

A controlled industrial manufacture, satisfying the required quality requirements, is a significant challenge for developing 2D material-based GAA transistor technologies.

There is therefore a need for a method for manufacturing 2D material-based GAA transistors having an improved reproducibility and a limited manufacturing cost.

An aim of the invention is to propose such a reproducible, controlled manufacturing method, and limiting the manufacturing cost. Another aim of the invention is to overcome at least some of the disadvantages of known methods.

### SUMMARY

To achieve these aims, according to an embodiment, a method for manufacturing a microelectronic device is provided, comprising at least one transistor comprising at least two channels with the basis of a semiconductor material, a gate surrounding said channels, a source and a drain, said channels being stacked along a main direction z, said method comprising the following steps:
Providing, on a substrate, a stack along the main direction z comprising a plurality of first layers made of a first material alternated with a plurality of second layers made of a second material, the first and second materials being different from said semiconductor material forming each channel,
Forming in this stack, first openings defining first patterns,
Forming a sacrificial gate mounted on the first patterns and partially in the first openings,
Forming first spacers on the first patterns and bordering the sacrificial gate,
Forming in the first patterns, second openings defining second patterns,
Removing partially, from the second openings, the first material of the first layers selectively at the second material of the second layers, so as to form first spaces in vertical alignment with the first spacers,
Filling the first spaces with a dielectric material to form internal spacers,
Removing totally, from the second openings, the second material of the second layers selectively at the first material of the first layers, so as to form second spaces and to expose parts of the sacrificial gate,
Forming a dielectric layer, called gate dielectric layer, in the second spaces, on the exposed parts of the sacrificial gate and remaining parts of the first layers, in vertical alignment with the sacrificial gate,
Depositing a layer with the basis of a semiconductor material in the second spaces, on the gate dielectric layer, in vertical alignment with the sacrificial gate and first spacers, so as to form:
   channels with the basis of the semiconductor material in vertical alignment with the sacrificial gate, and
   a source and a drain with the basis of the semiconductor material in vertical alignment with the first spacers,
Forming, preferably, source and drain contacts in the second openings,
Removing the sacrificial gate so as to form third openings,
Removing totally, from the third openings, the first material of the remaining parts of the first layers, so as to form third spaces surrounding the channels with the basis of the semiconductor material,
Filling with a material, called gate material, the third spaces, so as to form a so-called gate-all-around totally surrounding the channels of the at least one transistor.

A principle of the method according to the invention consists of selectively replacing certain layers of the initial stack with a semiconductor material in order to form the channels of the transistor. The initial stack does not comprise the semiconductor material. The subsequent deposition of the semiconductor material aims to better preserve the semiconductor material. According to a preferred option, the semiconductor material is a two-dimensional (2D) material chosen from among MX2 transition metal dichalcogenides, with M taken from among molybdenum (Mo) or tungsten (W), and X taken from among sulphur(S) or selenium (Se).

Thus, contrary to known methods, which consider the formation of 2D material-based layers in the initial stack, from the start of the method, the method according to the invention makes it possible to introduce 2D material layers at the end of the method, after structuration of the stack and, in particular, after the formation of the internal spacer. This advantageously makes it possible to limit the risk of degrading the 2D material during the method. The 2D material is not exposed to all the steps of the manufacturing method. The 2D material is thus preserved.

Moreover, the 2D material layers are not freely suspended during the method according to the invention. The gate dielectric layer coats and holds the 2D material parts around which the gate-all-around is formed. The mechanical strength is improved. The integrity of the structure is thus preserved.

Furthermore, the late introduction of the 2D material during the manufacturing method makes it possible to use standard microelectronic technologies for the formation and the structuration of the stack. It is not necessary to modify or adapt the standard structuration technological steps to the limitations of using the 2D material. The costs of the method are thus advantageously limited. The method can further be more easily implemented in current production lines.

Other aims, features and advantages of the present invention will appear upon examining the description below and the accompanying drawings. It is understood that other advantages can be incorporated.

### BRIEF DESCRIPTION OF THE FIGURES

Figures nA (n=1 . . . 16) schematically illustrate, along cross-sections xz of the steps of manufacturing a superposed transistor device, according to embodiments of the present invention.

Figures nB (n=1 . . . 16) schematically illustrate, along cross-sections yz indicated in the corresponding figures nA, the same steps of manufacturing the device, according to embodiments of the present invention.

FIGS. 11A, 12A and 11B, 12B illustrate, in particular, alternative steps to the step illustrated in FIGS. 10A, 10B.

In the figures in cross-sections, cutting planes are indicated (A-A′, B-B′, . . . , P-P′) with crossed references to the cutting planes of the corresponding figures. The drawings are given as examples and are not limiting of the invention. They constitute principle schematic representations intended to facilitate the understanding of the invention and are not necessarily to the scale of practical applications. In particular, in the principle diagrams, the thicknesses and/or the dimensions of the different layers, patterns and raised elements are not representative of reality. For reasons of clarity, all of the alphanumeric references are not systematically repeated from one figure to another. It is understood that the elements already described and reference, when they are reproduced in another figure, typically have the same alphanumeric references, even if these are not explicitly mentioned. A person skilled in the art will identify, without difficulty, one same elements reproduced in different figures.

### DETAILED DESCRIPTION

Before starting a detailed review of embodiments of the invention, optional features are stated below, which can optionally be used in association or alternatively:

According to an example, the stack comprises an alternance of a first layer with a second layer. Preferably, said first layer and said second layer are in contact. According to an example, the final device comprises transistor channels formed after selective removal of the second layers from the initial stack. According to an example, the final device comprises gates-all-around formed after selective removal of the first layers from the initial stack. The initial stack does not typically comprise the semiconductor material of the transistor channels, nor the material of the gates-all-around. According to an alternative option, the transistor channels are formed after selective removal of the first layers from the initial stack and the gates-all-around are formed after selective removal of the second layers from the initial stack.

According to an example, the internal spacers are silicon nitride-based. The internal spacers are preferably in contact with the remaining parts of the first layers. Before formation of the internal spacers, the partial removal of the first material from the first layers is configured to preserve parts of the first layers between the first spaces. These parts are called remaining parts. The remaining parts of the first layers are thus located between the first spaces, along a direction of the plane xy.

The deposition of the semiconductor material-based layer is done in the second spaces, between the remaining parts of the first layers and the sacrificial gate, along the main direction z. According to an example, the deposition of the semiconductor material-based layer is also done on flanks of the second patterns substantially parallel to the main direction z, in particular on flanks of the first spacers and on flanks of the internal spacers. This makes it possible to facilitate the return of the source and drain contacts in the device.

According to an example, the deposition of the semiconductor material-based layer is configured to form semiconductor material-based lateral layer portions on flanks of the second pattern substantially parallel to the main direction z, and semiconductor material-based horizontal layer portions in the second spaces, such that the lateral portions are thicker than the horizontal portions. Thicker lateral portions make it possible to decrease the contact resistance of the source and drain contacts. The channels of the transistor are formed in the horizontal portions.

According to an example, the deposition of the semiconductor material-based layer is configured to form semiconductor material-based lateral layer portions on the first spacers and on the internal spacers.

According to an example, the method comprises a formation of source and drain contacts in the second openings.

According to an example, the formation of the gates-all-around is done after the deposition of the semiconductor material-based layer. This type of method, typically called “gate last” where the functional gate is formed at the end of the method, replacing a sacrificial gate, makes it possible to preserve the dimensional features of the gate. This makes it possible to obtain a better control of the threshold voltage of MOSFET transistors. The thermal budget linked to the deposition of the semiconductor material does not impact the equivalent gate oxide thickness to the interface with the gate. The structural and electric features of the functional gate are better controlled.

According to an example, the deposition of the semiconductor material-based layer is done by chemical vapour deposition or by atomic layer deposition. The chemical vapour depositions are easy to implement. The atomic layer depositions make it possible to precisely control the thickness of the semiconductor material-based layer. These depositions make it possible to obtain a very good conformity for the semiconductor material-based layer.

According to an example, the semiconductor material is chosen from among MX2 transition metal dichalcogenides with M taken from among molybdenum (Mo) or tungsten (W), and X taken from among sulphur(S), selenium (Se) or tellurium (Te).

According to another example, the semiconductor material chosen with the basis of a semiconductor oxide, for example, IGZO (indium gallium zinc oxide)-, In2O3-, IWO (tungsten-doped indium oxide)-, ITO (indium tin oxide)-, IAZO (indium aluminium zinc oxide)-, InGaZnO-, InGaO-, InZnO-based, or an amorphous semiconductor oxide.

According to an example, the first material is chosen as SiGe and the second material is chosen as Si, or vice versa. These materials can be easily epitaxially grown by conventional microelectronic technological methods. This makes it possible to benefit from current technological methods. The cost of the method is reduced.

According to an example, the formation of the sacrificial gate is done such that the sacrificial gate extends over the entire height of the first openings. According to an example, the first openings extend along the entire height of the stack of the first and second layers. The sacrificial gate extends over the entire height of the stack. The sacrificial gate typically bears on the substrate. This makes it possible to give access to all the layers of the stack via the third openings.

According to an example, the second patterns each comprise a central part in vertical alignment with the sacrificial gate and first and second peripheral parts on either side of the central part, in vertical alignment with the first spacers.

According to an example, the deposition of the semiconductor material-based layer is configured such that the semiconductor material-based layer totally fills the second spaces.

According to another example, the deposition of the semiconductor material-based layer is configured such that the semiconductor material-based layer partially fills the second spaces. According to an example, the method further comprises, after deposition of the semiconductor material-based layer, a deposition of a dielectric layer configured to fill the second spaces. This makes it possible to form a thin semiconductor material-based layer, without limitation on the thickness of the second layers of the stack. The semiconductor material-based layer can have a thickness less than that of the second layers of the initial stack.

According to an example, the substrate is a silicon-based solid substrate.

According to an example, the stack comprises at least three first layers of the first material alternated with three second layers of the second material.

According to an example, the stack comprises as many first layers of the first material as second layers of the second material.

According to an example, the first openings are formed along a longitudinal direction x and the second openings are formed along a transverse direction y perpendicular to the longitudinal direction x, said first and second openings extend up to the substrate.

According to an example, the removal of the first material from the first layers selectively at the second material of the second layers is done by a first selective etching having a selectivity S_{10:20} of at least 5:1, preferably at least 10:1. This first selective etching is typically stopped at the time.

According to an example, the removal of the second material from the second layers selectively at the first material of the first layers is done by a second selective etching having a selectivity S_{20:10} of at least 5:1, preferably at least 10:1.

According to an example, the deposition of the semiconductor material-based layer is configured to form semiconductor material-based lateral layer portions on flanks of the second pattern in the second openings. According to an example, the method further comprises a formation of source and drain contacts in said second openings and on the semiconductor material-based lateral layer portions, before the removal of the sacrificial gate.

Unless incompatible, it is understood that all of the optional features above can be combined, so as to form an embodiment which is not necessarily illustrated or described. Such an embodiment is clearly not excluded from the invention. The features and the advantages of an aspect of the invention, for example, the device or the method, can be adapted mutatis mutandis to the other aspect of the invention.

The invention generally relates to a method for manufacturing a GAA transistor microelectronic device. Such a microelectronic device can have a “GAA stacked nanosheet”-type architecture, i.e. with stacked nanosheets and totally gate-all-around. A stacked nanowire and totally gate-all-around architecture is also possible.

The nanowires or nanosheets typically each comprise a conduction channel of a transistor. These channels are stacked along a direction z. This means that they each occupy a given altitude level along the direction z. A level can be defined between two planes perpendicular to the direction z.

Advantageously, the method according to the invention can be implemented to produce MOS GAA transistors for 5 nm and sub-5 nm technological nodes.

A microelectronic device comprising superposed GAA transistors can be advantageously integrated in logic systems having 3D architectures. These transistors can, in particular, be associated with other structural or functional elements, so as to design complex systems.

A particular aspect of the invention relates to the implementation of 2D materials to produce the nanowires or nanosheets of the device.

The 2D materials typically correspond to compounds having a lamellar structure constituted of two-dimensional sheets, stacked along the crystallographic axis c. The atomic bonds within each sheet are strong, of covalent nature. The bonds between sheets are a lot weaker, of the Van der Waals type. These two-dimensional sheets are also called monolayers.

In the scope of the present invention, the monolayers are preferably semiconductor monolayers of the MX2 type, where M is molybdenum (Mo) or tungsten (W) and X of sulphur(S) or selenium (Se). Each “monolayer” is, in this case, composed of a metal cation plane M inserted between two anion planes X. A monolayer, therefore, in this case, typically comprises three atomic planes: the atoms of the transition metal (Mo or W) form a plane sandwiched between two chalcogenide planes (S, Se or Te, for example). Each transition metal atom is connected to six chalcogenide atoms. These anions are in prismatic trigonal coordination with respect to the metal atoms. The MX2 transition metal dichalcogenide monolayers have a hexagonal atomic array.

The MX2 transition metal dichalcogenide monolayers are preferably MoS2, MoSe2, MoTe2, WS2, WSe2 molybdenum disulphide-based.

An alternative option relates to the implementation of semiconductor oxides to produce the nanowires or nanosheets of the device, for example, IWO, IGZO, ITO, InGaZnO, InGaO, InZnO, In2O3, IAZO. Another option relates to the implementation of graphene, hexagonal boron nitride “h-BN”, phosphorene (also known as “Black Phosphorous” BP), in particular in the form of a monolayer.

It is specified that, in the scope of the present invention, the terms “on”, “surmounts”, “covers”, “underlying”, “opposite” and their equivalents do not necessarily mean “in contact with”. Thus, for example, the deposition or the application of a first layer on a second layer, does not compulsorily mean that the two layers are directly in contact with one another, but means that the first layer at least partially covers the second layer by being either directly in contact with it, or by being separated from it by at least one other layer or at least one other element.

By a substrate, a film, a layer “with the basis” of a material A, this means a substrate, a film, a layer comprising this material A only or this material A and optionally other materials, for example, doping elements or alloy elements. Thus, a silicon nitride SiN-based spacer can, for example, comprise non-stoichiometric silicon nitride (SiN), or stoichiometric silicon nitride (Si3N4), or also a silicon oxynitride (SiON).

The word “dielectric” qualifies a material of which the electric conductivity is sufficiently low in the given application to serve as an isolator. In the present invention, a dielectric material preferably has a dielectric constant less than 20. In the present invention, the dielectric layer can have ferroelectric properties.

Several embodiments of the invention implementing successive steps of the manufacturing method are described below. Unless explicitly mentioned, the adjective “successive” does not necessarily imply, even if this is generally preferred, that the step immediately follow one another, intermediate steps being able to separate them.

Moreover, the term “step” means the carrying out of some of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of the phases of the method.

By “selective etching with respect to” or “etching having a selectivity with respect to” means an etching configured to remove a material A or a layer A with respect to a material B or a layer B, and having an etching speed of the material A greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

The different patterns formed during the manufacturing steps typically have a structure intended to evolve during the steps of the method. Thus, the patterns can comprise sacrificial layers of the initial stack, the 2D material- or semiconductor oxide-based layers, the dielectric layers, continuous or discontinuous. The different patterns aim to form, at the end of the method, “transistor patterns”, each comprising at least one conduction channel and a gate surrounding said channel, a dielectric barrier separating the gate and the channel, a source and a drain on either side of the channel. The congregation of the first and second layers in the initial stack can be inverted.

A preferably orthonormal system, comprising the axes x, y, z is represented in the accompanying figures.

In the present patent application, preferably thickness will be referred to for a layer or a film, and height will be referred to for a device or a structure. The thickness is taken along a direction normal to the main extension plane of the layer or of the film. Thus, a superficial silicon layer (topSi) typically has a thickness along z. A gate pattern formed on such a superficial layer has a height along z. The relative terms “on”, “surmounts”, “under”, “underlying” refer to positions taken along the direction z. A “lateral” dimension corresponds to a dimension along a direction of the plane xy. By a “lateral” extension or “laterally”, this means an extension along one or more direction of the plane xy.

An element located “in vertical alignment with” or “to the right of” another element means that these two elements are both located on one same line perpendicular to a plane in which a lower or upper face of a substrate mainly extends, i.e. on one same line oriented vertically in the figures in cross-section.

The terms “substantially”, “about”, “around” mean plus or minus 10%, and preferably plus or minus 5%. Moreover, the terms “between . . . and . . . ” and equivalent mean that the limits are inclusive, unless otherwise mentioned.

The description below has an example of an implementation of the method according to the invention in a context of developing a complex 3D device. The scope of this description is clearly not limiting of the invention.

FIGS. 1A, 1B to 16A, 16B schematically illustrate steps of manufacturing a device comprising stacked GAA transistors. Figures nA (n=1 . . . 16) correspond to first cross-sections, each illustrating a different step of the manufacturing method. Figures nB (n=1 . . . 16) correspond to second cross-sections, each illustrating the same step as the corresponding figure nA.

As illustrated in FIGS. 1A, 1B, a first step consists of producing a stack E of semiconductor layers 10, 10 on a substrate S. The substrate S can be an SOI (Silicon On Insulator), GeOI (Germanium On Insulator)- or SGOI (Silicon-Germanium On Insulator)-type substrate. These known substrates comprise, according to current terminology for a person skilled in the art, a so-called “Si bulk” thick silicon layer S1, a so-called “BOX” (Buried Oxide) silicon oxide layer S2, and a thin superficial layer, respectively silicon-, germanium- or silicon-germanium-based. This superficial thin layer can advantageously correspond to the first layer 10 of the stack E.

Alternatively, the substrate S can be an “Si bulk” solid substrate.

The stack E comprises, according to an example, an alternance of first silicon-germanium (SiGe) layers 10 and of second silicon (Si) layers 20.

The concentration of Ge in the SiGe alloy can be 20%, 30% or 45% for example. This concentration of germanium is chosen, so as to enable a good selectivity of the etching of SiGe with respect to Si, during the selective etching steps. The greater the concentration of Ge will be, the greater the Si selectivity will be during the subsequent removal of SiGe. This stack E is advantageously formed by epitaxy of the SiGe 10 and Si 20 layers. This step of forming the stack E is inexpensive and well-known to a person skilled in the art. The thicknesses of the Si and SiGe layers can be typically around 10 nm, and more generally between 5 nm and 20 nm, for example. In a known manner, in order to avoid the formation of structural defects, the maximum thicknesses permitted for the SiGe layers 10 depend, in particular, on the concentration of Ge chosen.

In the example illustrated in FIGS. 1A, 1B, three SiGe layers 10 are alternated with three epitaxially grown Si layers 20. A super Si/SiGe array is thus obtained. The number of Si and SiGe layers can naturally be increased. This ultimately makes it possible to increase the number of stacked transistors in the final device.

Generally, the first material of the first layers 10 and the second material of the second layers 20 are chosen, such that one can be selectively etched with respect to the other. Thus, other pairs of first and second materials are possible. By respecting this selectivity condition to the etching, the first and second materials can be chosen from among dielectric materials (oxides and nitrides, for example), semiconductor materials, metallic materials.

As illustrated in FIGS. 2A, 2B, a conventional lithography/etching step is carried out, in order to define first patterns 101M, and first openings 100. The etching is anisotropic and directed along z. It is configured to etch the stack E, in this case, the super Si/SiGe array, over its entire height, by stopping on the substrate S, in this case, the BOX S2. It can be done by plasma by using an HBr/O2 etching chemistry. The first patterns 101M can have a length L₁ along x of between 10 nm and 500 nm. They preferably have a width I₁ along y of between 10 nm and 120 nm, for example, around 40 nm. This first structuration of the stack E in the form of fins, makes it possible to define a plurality of superposed nanowires or nanosheets.

For clarity, the following figures iB (i=3 . . . 16) only illustrate one single “fin” pattern 101M.

As illustrated in FIGS. 3A, 3B, sacrificial gates 150 are then formed on the “fin” patterns 101M. The formation of these sacrificial gates 150 is done typically by lithography/etching. The formation of the sacrificial gates 150 is configured, such that the sacrificial gates 150 are mounted on the “fin” patterns 101M, as illustrated in FIG. 3B. The sacrificial gates 150 typically comprise an upper part located on the “fin” pattern 101M, and lateral parts located on the lateral flanks of the “fin” pattern 101M. The sacrificial gates 150 typically bear on the substrate S. At this stage, the sacrificial gates 150 are typically surmounted by an etching mask 160, called hard mask, implemented in the structuration of the sacrificial gates 150. The sacrificial gates 150 are, for example, polycrystalline silicon-based. A thin SiO₂ oxide layer, 7 nm thick, for example, is preferably deposited prior to the formation of the sacrificial gates 150. This thin SiO₂ oxide layer (not illustrated in the figures) is thus inserted between the sacrificial gates 150 and the “fin” patterns 101M. This thin SiO₂ oxide layer can form a stop layer for the subsequent etching of the sacrificial gates 150.

As illustrated in FIGS. 4A, 4B, first spacers 170 are then formed on the flanks oriented along yz of the sacrificial gates 150. Generally, projecting along z, these spacers form a continuous ring around each sacrificial gate 150, with a closed contour. However, in cross-section, along the plane xz illustrated in FIG. 4A, the first spacer 170 has two parts opposite one another on each of the flanks of the sacrificial gate 150. These two parts are generally designated as being the first spacers 170, even if these can be considered as belonging to one single and same spacer. The first spacers 170 typically extend up to an upper face of the hard masks 160. The first spacers 170 are typically silicon nitride SiN-based or with the basis of a dielectric material with low dielectric constant, for example, SiCO-based.

As illustrated in FIGS. 5A, 5B, after formation of the first spacers 170 by deposition/etching, the anisotropic etching along z is extended in order to define second patterns 102M, and second openings 200. The etching is configured to etch the stack E over its entire height, by stopping on the substrate S. It can be done by plasma by using an HBr/O2 etching chemistry.

As illustrated in FIGS. 6A, 6B, after formation of the second openings 200, the first layers 10 are partially etched selectively at the second layers 20, at the substrate S and at the first spacers 170. The etching of the first material of the first layers 10 typically has a selectivity S_{10:20} with respect to the second material of the second layers 20, of at least 5:1, preferably at least 10:1. This partial etching aims to form first spaces 11 in vertical alignment with the first spacers 170. This partial etching is typically stopped at the time. It has an isotropic character and can be done wet or dry, from the second openings 200. From this partial etching, the central parts of the first layers 10 are preserved under the sacrificial gates 150.

As illustrated in FIGS. 7A, 7B, the first spaces 11 are then filled with a dielectric material, for example with silicon nitride or with a dielectric with low permittivity, to form internal spacers 171. These “internal” spacers 171 are integrated in the stack E, preferably in vertical alignment with the first spacers 170. They are in contact with the central parts of the first layers 10. The formation of the internal spacers 171 is done typically from the second openings 200.

As illustrated in FIGS. 8A, 8B, the second layers 20 are then etched selectively at the central parts of the first layers 10 and at the internal spacers 171. The etching of the second material of the second layers 20 typically has a selectivity S_{20:10} with respect to the first material of the first layers 10, of at least 5:1, preferably at least 10:1. This total etching can be stopped at the time, possibly after an overetching time aiming to guarantee the total removal of the second material from the second layers 20. This total etching has an isotropic character and can be done wet or dry, from the second openings 200. From this etching, the second layers 20 are totally removed to form second spaces 21. The central parts of the first layers 10 are maintained by the sacrificial gates 150, as illustrated in FIG. 8B.

As illustrated in FIGS. 9A, 9B, a dielectric layer 30 is then deposited in the second spaces 21. This dielectric layer 30 is typically with the basis of a material with high permittivity, for example, HfO2-based. The dielectric layer 30 is intended to form the gate dielectric layer between the channels of the GAA transistors and their gates-all-around. It can be formed by chemical vapour deposition (CVD), by metal organic chemical vapour deposition (MOCVD), or by atomic layer deposition (ALD). It thus covers at least the central parts of the first layers 10 and the exposed lower face of the sacrificial gate 150, and preferably the internal spacers 171, and the first spacers 170. The dielectric layer 30 typically has a thickness of between 1 nm and 5 nm. According to an alternative example, this layer 30 can be with the basis of a ferroelectric material such as Si-doped HfZrO2, HZO, HfO2, for example. Such a ferroelectric layer 30 can be advantageously used to produce FeFET (ferroelectric field-effect transistor)-type memory transistors.

As illustrated in FIGS. 10A, 10B, according to a first embodiment, a layer 40 with the basis of a semiconductor material is then deposited on the gate dielectric layer 30 in the second spaces 21. The deposition of the semiconductor material is, in this case, configured such that the layer 40 totally fills the second spaces 21. The portions of the layer 40 located in the second spaces 21 thus have a fully controlled thickness, close to the thickness of the second initial layers. This layer 40 is intended to form the channels 41 of the GAA transistors in vertical alignment with the sacrificial gates 150 and with the central parts of the first layers 10. This layer 40 is also intended to form the sources 42 and the drains 43 of the GAA transistors in vertical alignment with first spacers 170 and with the internal spacers 171.

The layer 40 is also typically deposited outside of the second spaces 21, on the flanks of the first spacers 170 and of the internal spacers 171. This makes it possible to improve the reconnection with the sources 42 and the drains 43 of the GAA transistors. The layer 40 thus has horizontal portions in the second spaces 21, in particular, between the remaining parts of the first layers, and vertical portions on the flanks of the first spacers 170 and of the internal spacers 171. According to an option, the thickness of the vertical portions of the layer 40 is greater than the thickness of the horizontal portions of the layer 40. This makes it possible to reduce the contact resistance for the sources 42 and the drains 43 of the GAA transistors. The sources 42 and the drains 43 of the GAA transistors can comprise the horizontal portions in vertical alignment with first spacers 170 and with the internal spacers 171, and at least partially, the vertical portions on the flanks of the first spacers 170 and of the internal spacers 171.

The semiconductor material of the layer 40 is advantageously a two-dimensional material taken from among MX2 transition metal dichalcogenides with M, molybdenum (Mo) or tungsten (W), and X, sulphur(S), selenium (Se) or tellurium (Te). Such a 2D material can be advantageously deposited in the form of a thin layer comprising 1 to 10 atomic layers, preferably 1 to 5 atomic layers. The deposition of this 2D material can be done by CVD, MOCVD or ALD. According to another option, the semiconductor material of the layer 40 is a semiconductor oxide such as ITO (indium tin oxide), IGZO (indium gallium zinc oxide), IWO (tungsten-doped indium oxide), In2O3 indium oxide. According to another option, the semiconductor material of the layer 40 is a graphene, a hexagonal boron nitride “h-BN”, a phosphorene (also known as “Black Phosphorus” BP), in the form of a monolayer or of a thin layer comprising 1 to 10 atomic layers, preferably 1 to 5 atomic layers.

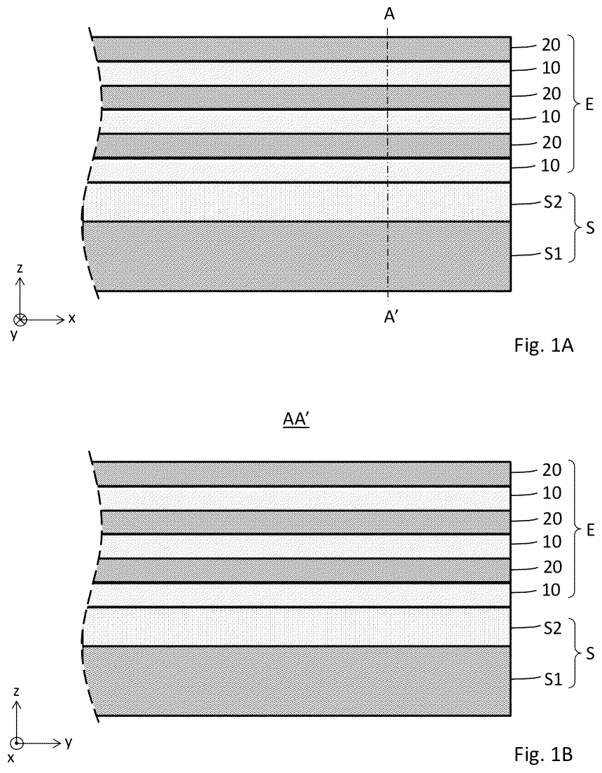

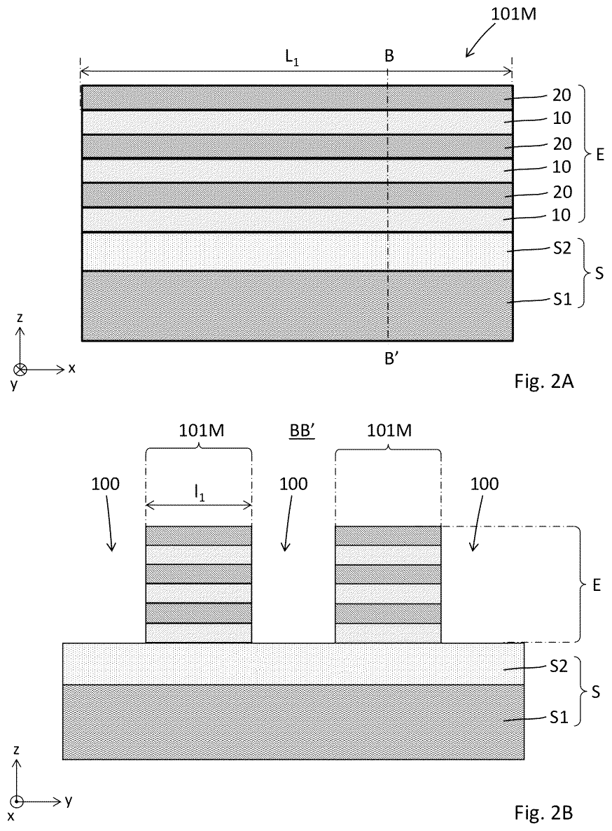

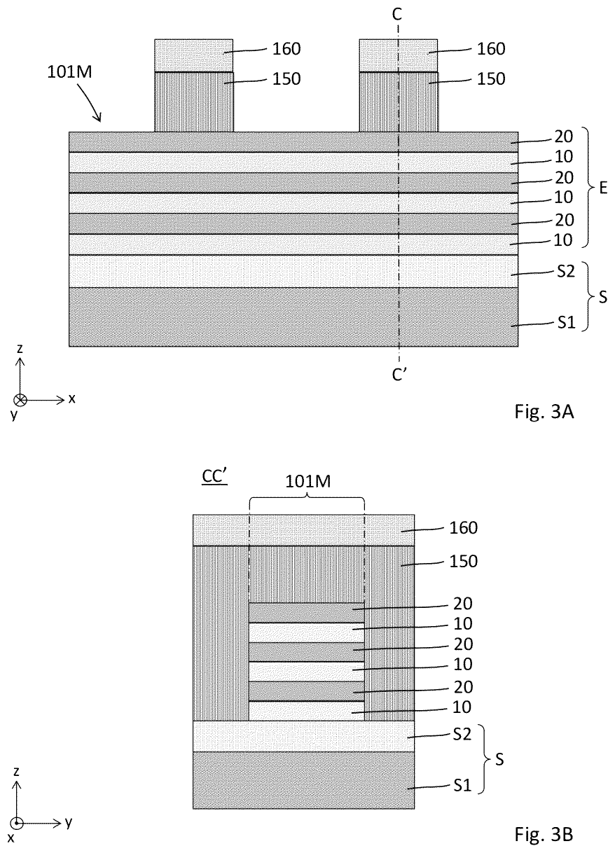

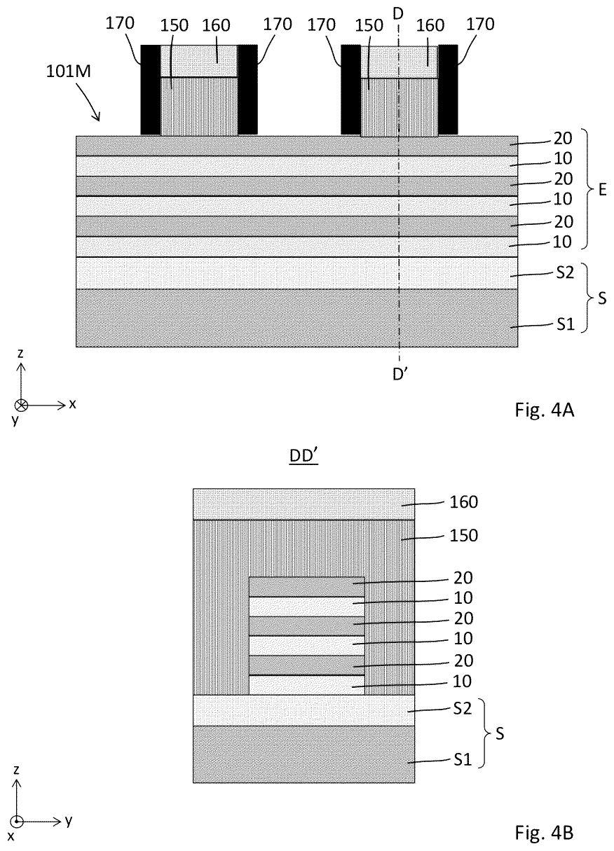

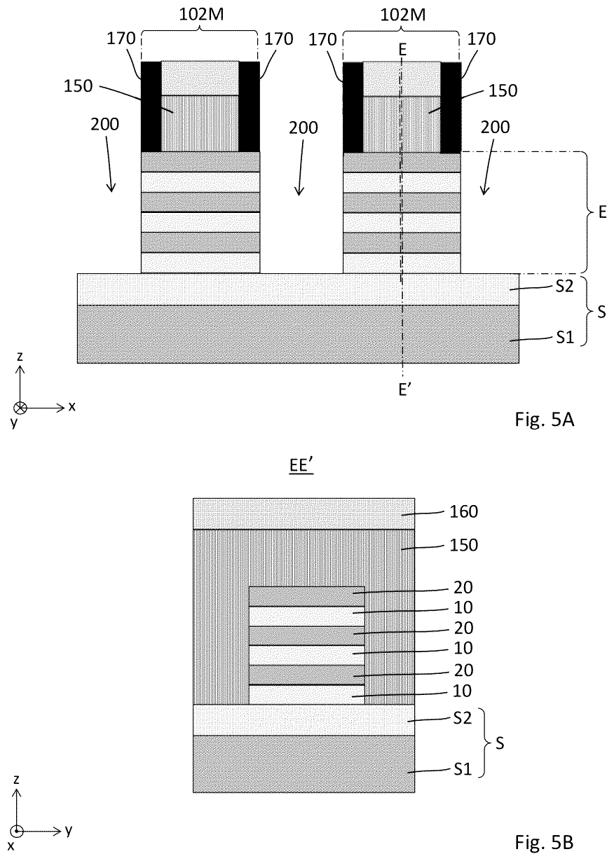

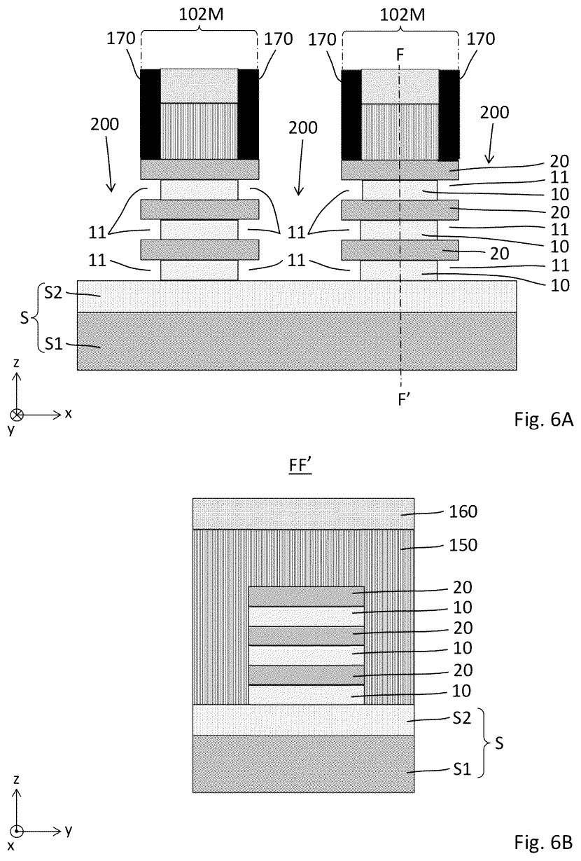

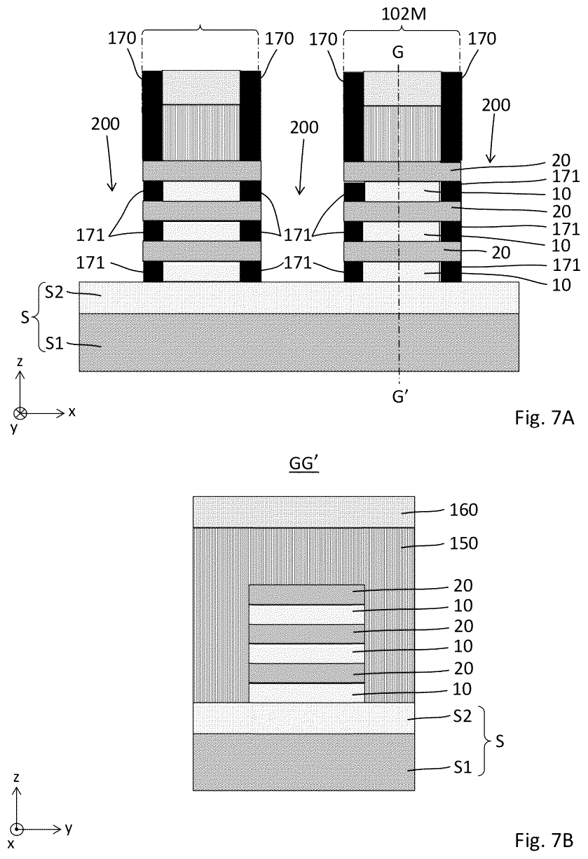

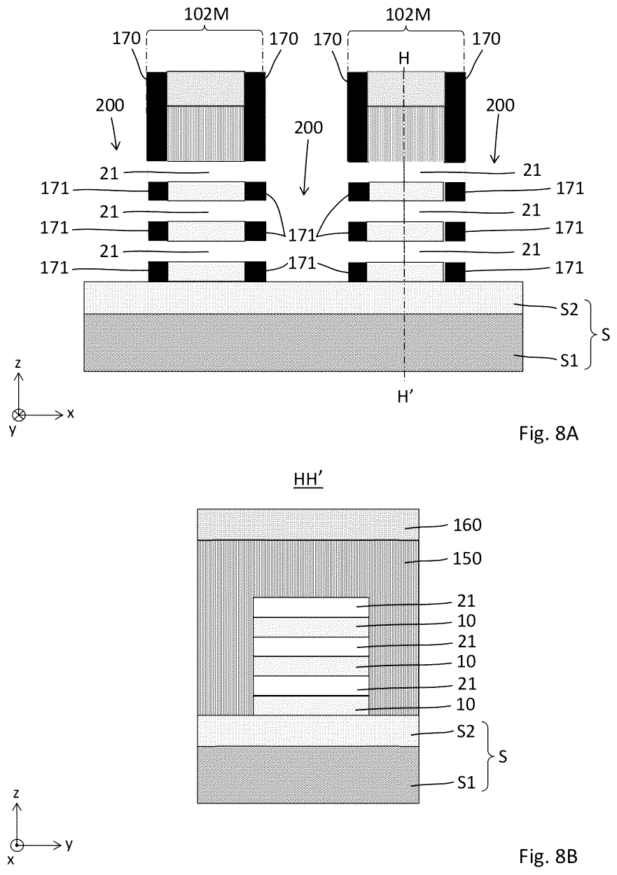

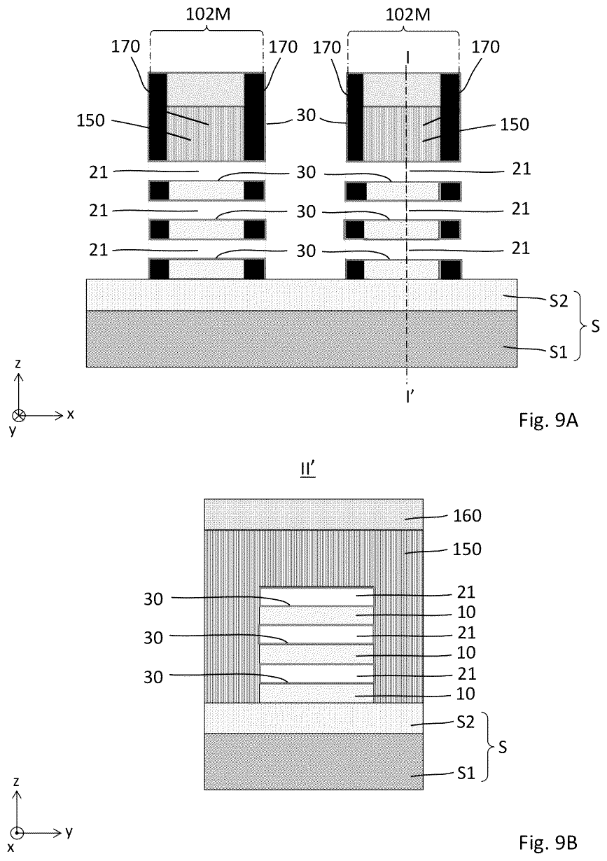

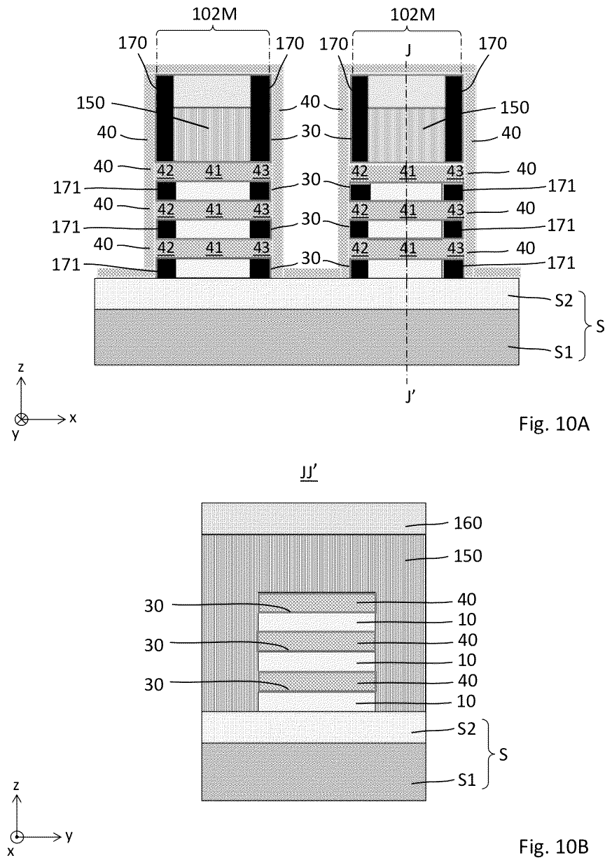

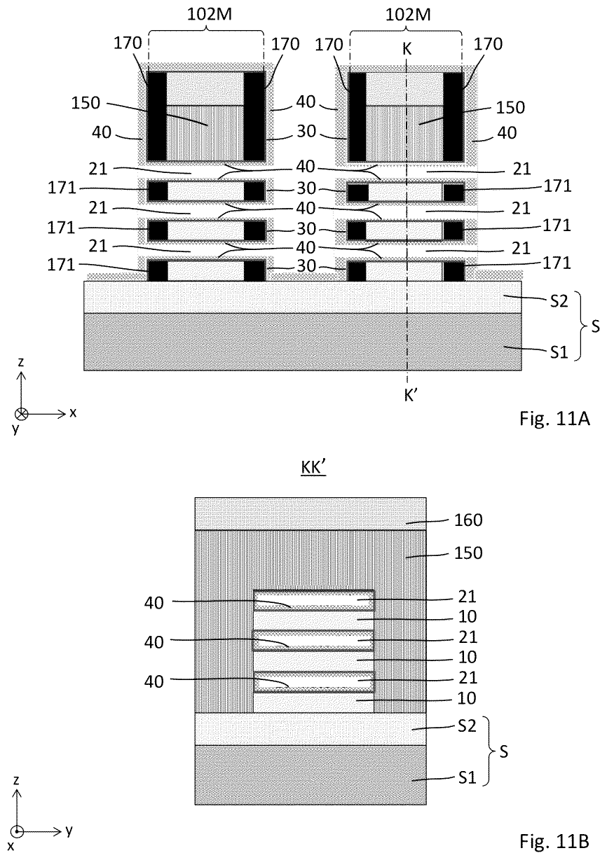

As illustrated in FIGS. 11A, 11B, according to a second embodiment, the semiconductor material-based layer 40 is deposited on the gate dielectric layer 30 in the second spaces 21 without totally filling the second spaces 21. In this case, the portions of the layer 40 located in the second spaces 21 can be significantly thinner than the second initial layers. These horizontal portions can have a thickness corresponding to a few atomic layers only, for example, between 1 and 5 atomic layers of semiconductor material. The reduction of thickness of the layer 40 makes it possible to improve the electrostatic control of the transistors and therefore to reduce the dimensions of the channels 41 of the GAA transistors. The performances of the GAA transistors can be improved.

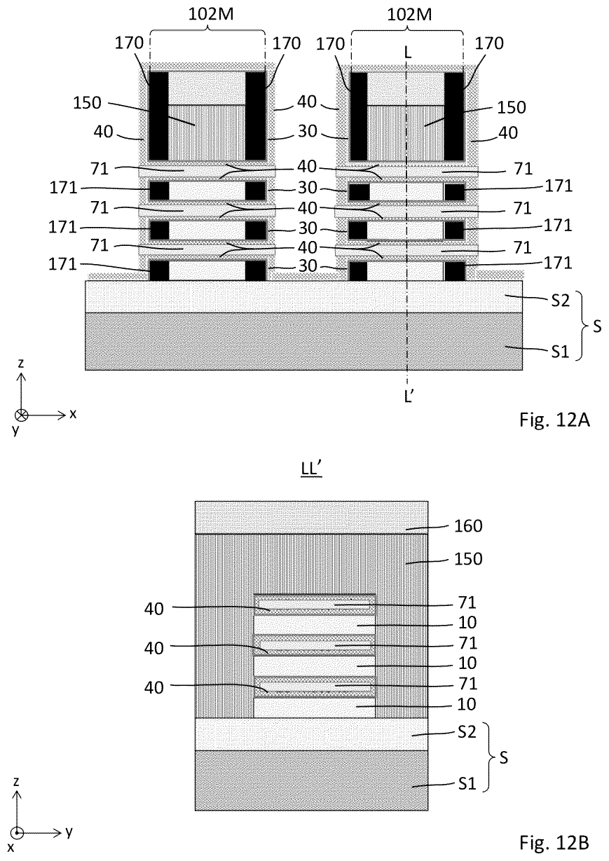

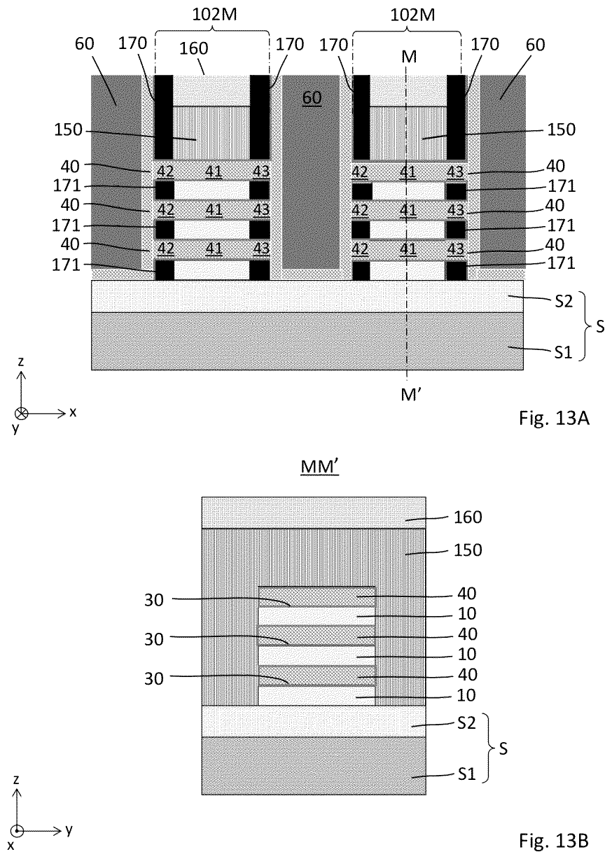

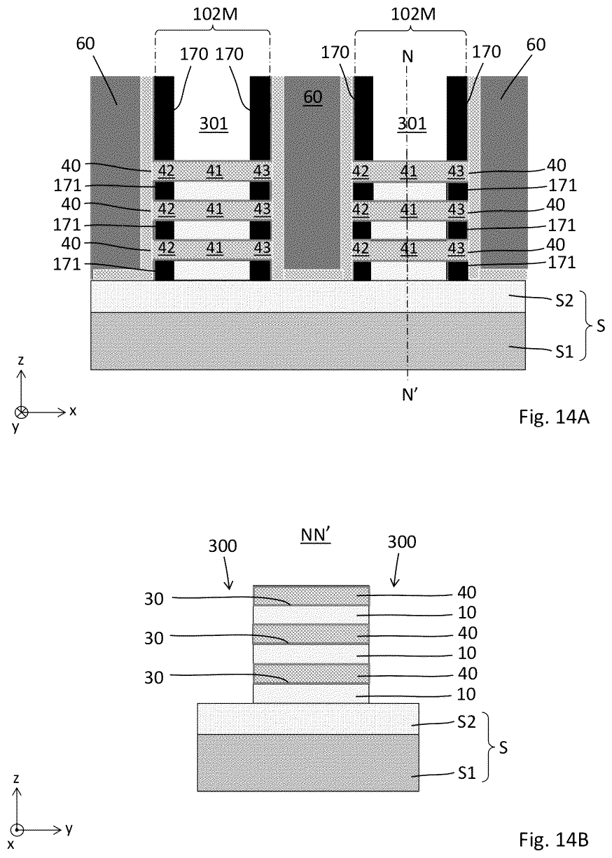

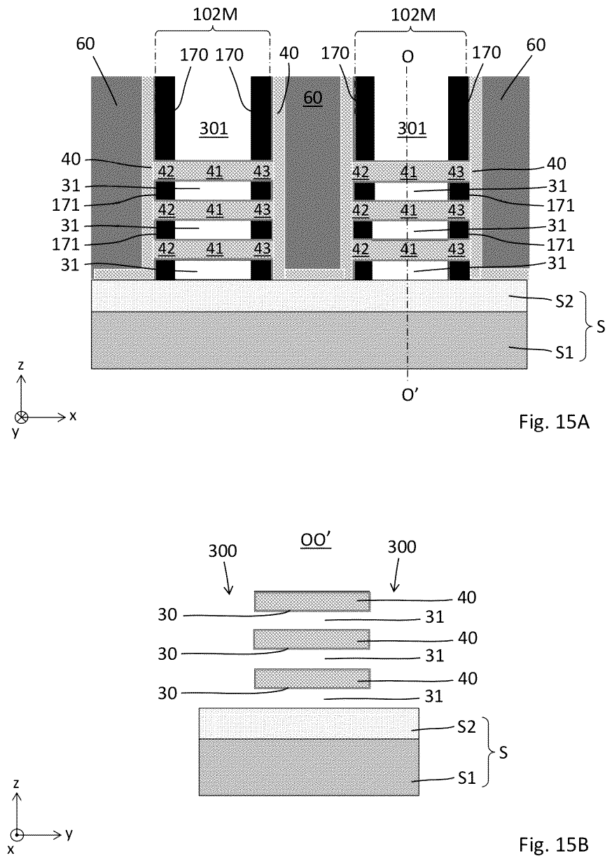

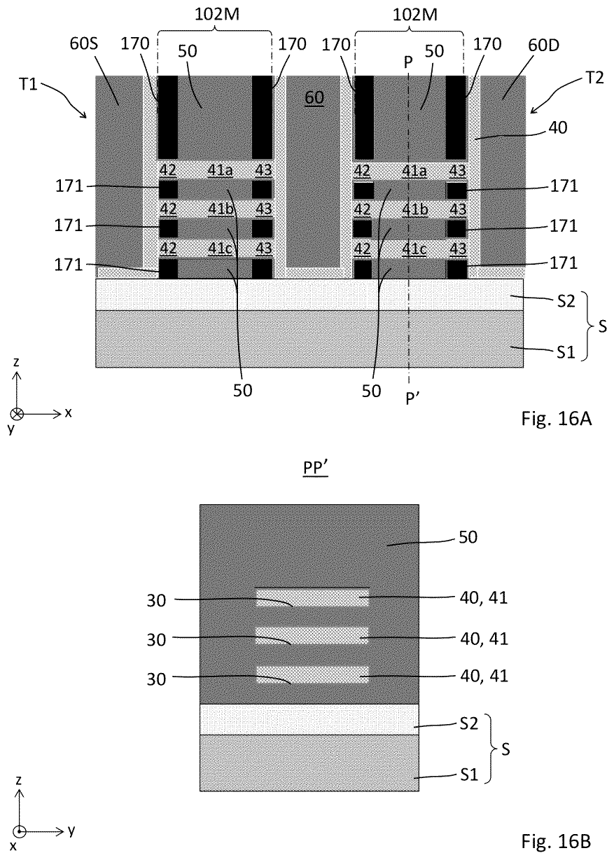

According to this second embodiment, as illustrated in FIGS. 12A, 12B, a dielectric stopper 71 is then formed between the horizontal portions of the layer 40, in order to fill the second spaces 21. This makes it possible to electrically isolate the GAA transistors from one another. This also makes it possible to improve the mechanical resistance of the device and/or avoid deformations of the channels of the GAA transistors, for example, by heating during operation. This dielectric stopper 71 can be formed by a CVD or ALD deposition, followed by an isotropic etching along z, conventionally.

As illustrated in FIGS. 13A, 13B, the second openings can then be filled with one or more metallic layers 60, for example, Ti-, TiN-, W-based, or with other metals making it possible to ensure a low contact resistance, such as Bi, Ni, Au, Sb, etc., in order to form the source and drain contacts. A chemical-mechanical polishing CMP is typically done in order to remove excess metal deposited on the patterns 102M. The hard masks 160 are thus exposed.

As illustrated in FIGS. 14A, 14B, the hard masks 160 are first removed, then the sacrificial gates 150 are also removed. This removal can be done by wet etching, stopping on the thin SiO2-based stop layer or another dielectric. The dielectric layer 30 is preserved. This wet etching typically has a high selectivity with respect to the stop layer and to the first spacers 170. This wet etching can be with the basis of a TMAH (tetramethylammonium hydroxide) or TEAH (tetraethylammonium hydroxide) ammoniac salt solution. The SiO2-based stop layer is then typically etched wet to expose the dielectric layer 30. This removal of the sacrificial gates 150 makes it possible to form a main space 301 and third openings 300 opening onto the central parts of the first layers 10 (FIG. 14B).

As illustrated in FIGS. 15A, 15B, the central parts of the first layers 10 are then totally removed by selective etching with respect to the dielectric layer 30, from the third openings 300. This etching aims to form third spaces 31 instead of the central parts of the first layers 10. This etching has an isotropic character and can be done wet or dry, from third openings 300.

As illustrated in FIGS. 16A, 16B, the main spaces 301 and the third spaces 31 are then filled with one or more metallic layers 50, for example TiN-, W-based, in order to form the gates-all-around of the GAA transistors. According to an option, before deposition of the metallic layers 50, a dielectric layer with the basis of a material with high permittivity, for example HfO2-based, is deposited beforehand in the main spaces 301 and the third spaces 31. This makes it possible to increase the thickness of the gate dielectric layer between the channels 41 of the GAA transistors and their gates-all-around 50. A chemical-mechanical polishing CMP is typically done in order to remove the excess metal deposited on the patterns 102M.

A microelectronic device comprising three transistors T1, T2, T3 stacked along z, with a gate-all-around 50, is thus advantageously obtained. The channels 41, the sources 42 and the drains 43 are preferably with the basis of a two-dimensional material. Source and drain contacts 60S, 60, 60D electrically connect these GAA transistors T1, T2, T3 stacked along z.

In view of the description above, it clearly appears that the method proposed offers a particularly effective solution to form 2D material-based stacked GAA transistors. This solution is further advantageously compatible with standard microelectronic methods. The invention is however not limited to the embodiments described above.

1. A method for manufacturing a microelectronic device comprising at least one transistor comprising at least two channels with the basis of a semiconductor material, a gate surrounding said channels, a source and a drain, said channels being stacked along a main direction, said method comprising the following steps:
providing, on a substrate, a stack along the main direction comprising a plurality of first layers made of a first material alternated with a plurality of second layers made of a second material, the first and second materials being different from the semiconductor material forming each channel,
forming, in the stack, first openings defining first patterns,
forming a sacrificial gate mounted on the first patterns and partially in the first openings,
forming first spacers on the first patterns and bordering the sacrificial gate,
forming, in the first patterns, second openings defining second patterns,
removing partially, from the second openings, the first material of the first layers selectively at the second material of the second layers, so as to form first spaces in vertical alignment with the first spacers,
filling the first spaces with a dielectric material to form internal spacers,
removing totally, from the second openings, the second material from the second layers selectively at the first material from the first layer, so as to form second spaces and to expose parts of the sacrificial gate,
a dielectric layer, called a gate dielectric layer, in the second spaces, on the exposed parts of the sacrificial gate and remaining parts of the first layers, in vertical alignment with the sacrificial gate,
depositing a layer with the basis of a semiconductor material in the second spaces, on the gate dielectric layer, in vertical alignment with the sacrificial gate and with the first spacers, so as to form:
channels with the basis of the semiconductor material in vertical alignment with the sacrificial gate, and
a source and a drain with the basis of the semiconductor material in vertical alignment with the first spacers,
removing the sacrificial gate so as to form third openings,
removing totally, from the third openings, the first material of the remaining parts of the first layers, so as to form third spaces surrounding the semiconductor material-based channels,
filling with a gate material, the third spaces, so as to form a gate-all-around, totally surrounding the channels of the at least one transistor.

2. The method according to claim 1, wherein the deposition of the semiconductor material-based layer is also performed on the first spacers and on the internal spacers.

3. The method according to claim 2, wherein the deposition of the semiconductor material-based layer is configured to form semiconductor material-based lateral layer portions on flanks of the second pattern substantially parallel to the main direction, and semiconductor material-based horizontal layer portions in the second spaces, such that the lateral portions are thicker than the horizontal portions.

4. The method according to claim 1, wherein the formation of the gate-all-around is performed after the deposition of the semiconductor material-based layer.

5. The method according to claim 1, wherein the deposition of the semiconductor material-based layer is performed by chemical vapour deposition or by atomic layer deposition.

6. The method according to claim 1, wherein the semiconductor material is a two-dimensional material chosen from among MX2 transition metal dichalcogenides, with M taken from among molybdenum or tungsten, and X taken from among sulphur, selenium or tellurium.

7. The method according to claim 1, wherein the semiconductor material is chosen with the basis of a semiconductor oxide, or graphene, hexagonal boron nitride or phosphorene.

8. The method according to claim 1, wherein the first material is chosen as SiGe and the second material is chosen as Si, or vice versa.

9. The method according to claim 1, wherein the formation of the sacrificial gate is performed such that the sacrificial gate extends over an entire height of the first openings.

10. The method according to claim 1, wherein the deposition of the semiconductor material-based layer is configured such that the semiconductor material-based layer totally fills the second spaces.

11. The method according to claim 1, wherein the deposition of the semiconductor material-based layer is configured such that the semiconductor material-based layer partially fills the second spaces, said method further comprising, after deposition of the semiconductor material-based layer, a deposition of a dielectric layer configured to fill the second spaces.

12. The method according to claim 1, wherein the substrate is a silicon-based solid substrate.

13. The method according to claim 1, wherein the first openings are formed along a longitudinal direction and the second openings are formed along a transverse direction perpendicular to the longitudinal direction, said first and second openings extending up to the substrate.

14. The method according to claim 1, wherein the stack comprises as many first layers of the first material as second layers of the second material.

15. The method according to claim 1, wherein the deposition of the semiconductor material-based layer is configured to form semiconductor material-based lateral layer portions on flanks of the second pattern in the second openings, the method further comprising a formation of source and drain contacts in said second openings and on the semiconductor material-based lateral layer portions, before the removal of the sacrificial gate.
